(19) United States
(12) Patent Application Publication
(10) Pub. No.: US 2011/0267755 A1
(43) Pub. Date: Nov. 3, 2011

(54) SIDE PANEL FORMING METHOD AND SIDE PANEL

(75) Inventor: YUN-LUNG CHEN, Tu-Cheng (TW)

(73) Assignee: HON HAI PRECISION INDUSTRY CO., LTD., Tu-Cheng (TW)

(21) Appl. No.: 12/884,691

(22) Filed: Sep. 17, 2010

(30) Foreign Application Priority Data
Apr. 30, 2010 (CN) 201010161110.8

(51) Int. Cl. H05K 7/00; B21D 35/00

(52) U.S. Cl. 361/679.6; 72/338

(57) ABSTRACT

The disclosure provides a side panel forming method and a side panel. The side panel forming method includes following steps. An original panel with a straight side edge is provided. The original panel is punched to form a tab with an edge of the tab aligned with the straight side edge. The tab is bent about a line parallel to the straight side edge in a first direction to form a securing portion. A first part of the original panel, is folded about a straight bending line, defined in the original panel in a second direction opposite to the first direction, to contact a second part of the original side panel to form a side panel. Wherein the first part of the original panel is defined between the straight bending line and the straight side edge, the straight bending line is substantially parallel to the straight side edge, and the securing portion is disposed between the straight bending line and the straight side edge.

### BACKGROUND

1. Technical Field

The present disclosure relates to side panel forming methods and side panels.

2. Description of Related Art

A computer usually includes a main body and a side panel mounted to the main body. A conventional side panel includes a bent portion. The bent portion includes a number of securing portions for engaging a main body of a computer. There is a distance between a part of the bent portion for forming each securing portion and a free edge of the bent portion. This uses more material for the formation of this type of side panel, which is a waste of resources.

### BRIEF DESCRIPTION OF THE DRAWINGS

FIG. 1 is an isometric view of an original side panel of one embodiment, the original side panel including a bent portion with a number of tabs.

FIG. 2 is another isometric view of an original side panel of an embodiment, the tabs being distorted.

FIG. 3 is an isometric view of a side panel of an embodiment which is formed from the original side panel of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

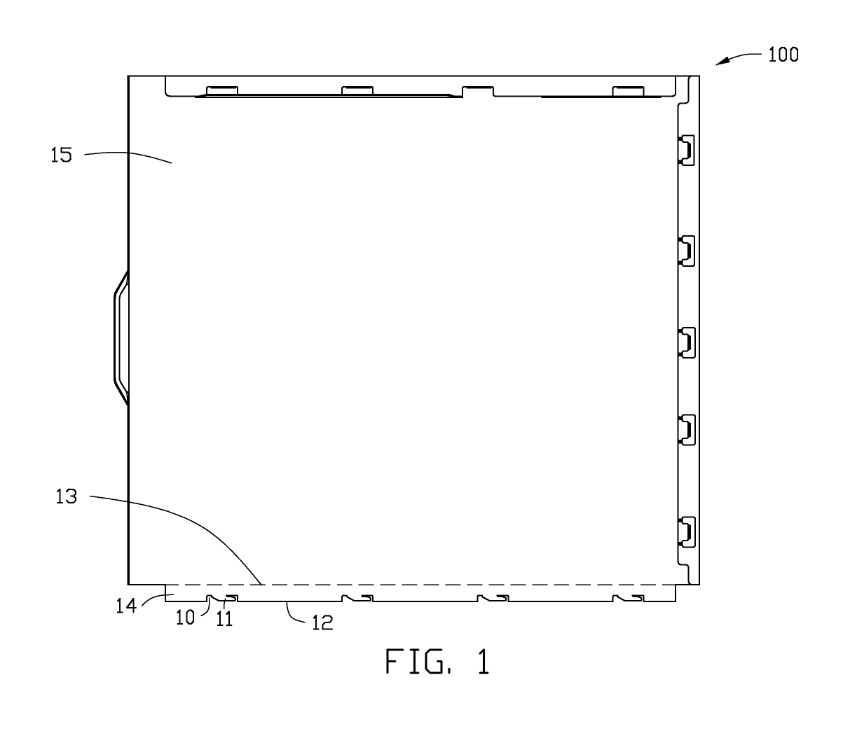

Referring to FIG. 1, a side of an original side panel 100 defines a straight side edge 12. The original side panel 100 is substantially rectangular. Other sides of the original side panel 100 include a number of formed portions (not labeled). The original side panel 100 includes a number of tabs 11 adjacent to the straight side edge 12. Each tab 11 corresponds to a punched opening 10. The punched opening 10 is formed when the original side panel 100 is punched to form each tab 11. These tabs 11 are on a plane defined by the original side panel 100. An edge of each tab 11 is aligned with the straight side edge 12. The original side panel 100 defines a straight bending line 13 that is substantially parallel to the straight side edge 12.

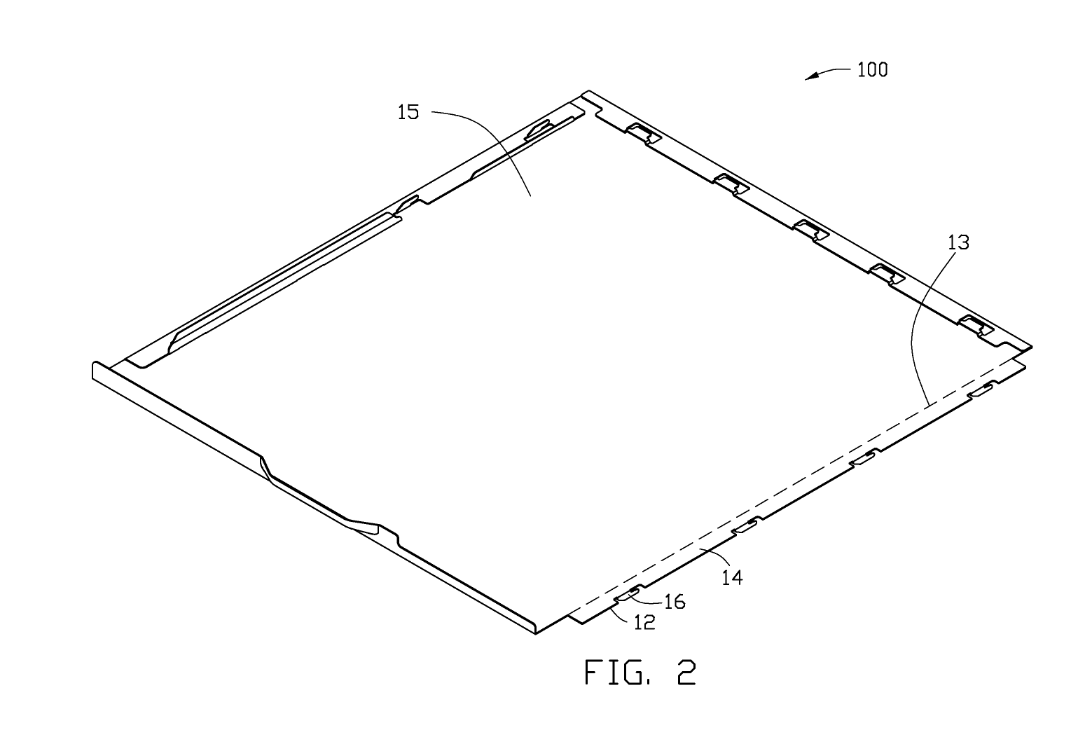

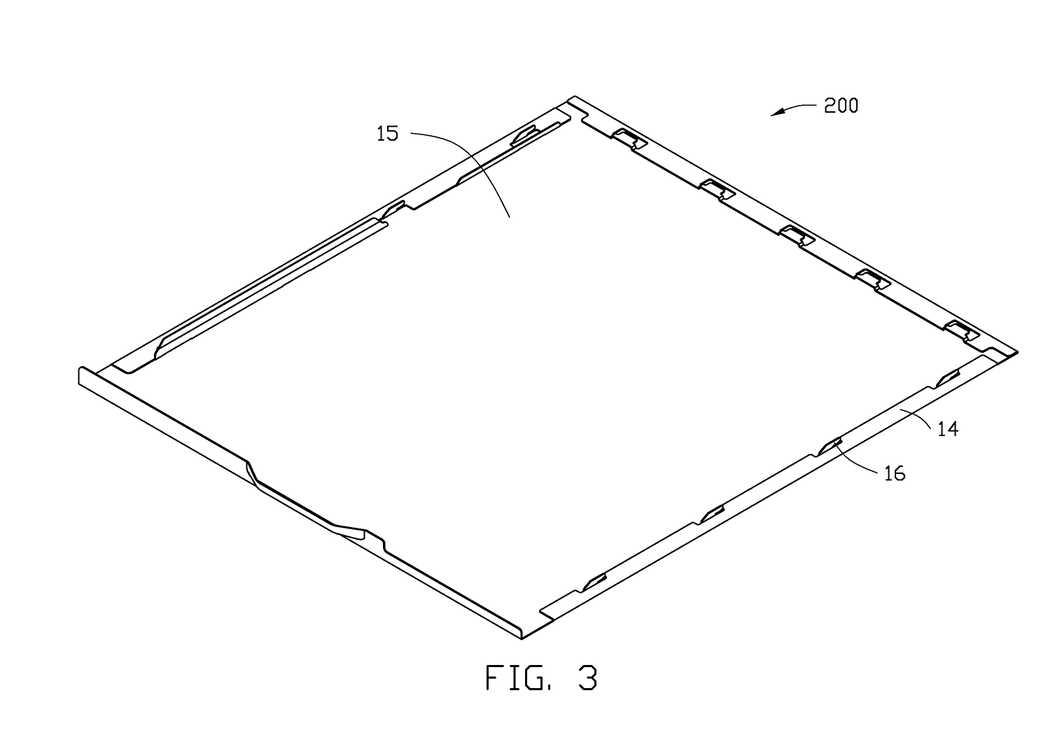

Referring to FIGS. 2 and 3, the original side panel 100 defines a side panel body 15 and a bent portion 14 between the straight bending line 13 and the straight side edge 12. The straight bending line 13 separates the side panel body 15 and the bent portion 14. Each tab 11 is distorted about a line substantially parallel to the straight side edge 12 at about 90 degrees in a first direction to form a securing portion 16. In one embodiment, the securing portion 16 is substantially lambdoid shaped hook and configured to engage with a main body of a computer enclosure (not shown). The bent portion 14 is distorted about the straight bending line 13 at about 180 degrees in a second direction opposite to the first direction to contact the side panel body 15, thereby forming a side panel 200. In one embodiment, the side panel 200 is a part of a computer and is secured to a main body of the computer with the securing portions 16.

In another embodiment, the width of each tab 11 in a direction substantially perpendicular to the straight side edge 12 is equal to a distance between the straight bending line 13 and the straight side edge 12.

A side panel forming method is described below.

An original panel is provided. The original panel is substantially rectangular. A side of the original panel defines the straight side edge 12.

The original panel is punched to form the tab 11 substantially adjacent to the straight side edge 12 of the original side panel, thereby forming the original side panel 100. An edge of the tab 11 is a part of the straight side edge 12.

Each tab 11 is bent about a line substantially parallel to the straight side edge 12 in the first direction at about 90 degrees to form the securing portion 16. The securing portion 16 is configured to engaging a main body of a computer enclosure (not shown).

The straight bending line 13 is defined on the original side panel substantially parallel to the straight side edge 12. The securing portion 16 is disposed between the straight bending line 13 and the straight side edge 12. A part of the original side panel 100 between the straight bending line 13 and the straight side edge 12 is defined as the bent portion 14 and the rest of the original side panel 100 is defined as the side panel body 15. The bent portion 14 is folded about the straight bending line 13 in the second direction to contact the side panel body 15, thereby forming the side panel 200.

It is to be understood, however, that even though numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method comprising:
providing an original panel, the original panel defining a straight side edge;
punching the original panel to form a tab, wherein an edge of the tab is aligned with the straight side edge;
bending the tab about a line substantially parallel to the straight side edge in a first direction to form a securing portion; and
folding a first part of the original panel about a straight bending line, defined in the original panel in a second direction opposite to the first direction, to contact a second part of the original side panel to form a side panel, wherein the first part of the original panel is defined between the straight bending line and the straight side edge, the straight bending line is substantially parallel to the straight side edge, and the securing portion is disposed between the straight bending line and the straight side edge.

2. The method of claim 1, wherein a width of the tab in a direction perpendicular to the straight side edge is equal to a distance between the straight bending line and the straight side edge.

3. The method of claim 1, wherein the securing portion is a hook configured to secure the side panel to a main body of a computer.

4. The method of claim 3, wherein the hook is L-shaped.

5. The method of claim 1, wherein the step of bending the tab comprises bending the tab in the first direction to form the securing portion at about 90 degrees.

6. A side panel, comprising:
a side panel body; and
a bent portion folded from the side panel body and contacting the side panel body, the bent portion defining a straight side edge and a straight bending line, the straight side edge is parallel to the straight bending line; the bent portion comprising a securing portion substantially perpendicular to the side panel body, and a width of the securing portion, in a direction perpendicular to the side panel body, is equal to a distance between the straight side edge and the securing portion.

7. The side panel of claim 6, wherein the width of the securing portion is equal to a distance between the straight bending line and the straight side edge.

8. The side panel of claim 6, wherein the securing portion is a hook configured to secure the side panel to a main body of a computer.

9. The side panel of claim 8, wherein the hook is L-shaped.

10. The side panel of claim 6, wherein an opening is defined in the bent portion corresponding to the securing portion.
